(19) United States
(12) Patent Application Publication
(10) Pub. No.: US 2009/0243012 A1
(43) Pub. Date: Oct. 1, 2009

(54) ELECTROMAGNETIC INTERFERENCE SHIELD STRUCTURES FOR SEMICONDUCTOR COMPONENTS

(75) Inventors: Kiran Kumar Vanam, Boise, ID (US); Derek J. Gochnour, Boise, ID (US); Alan G. Wood, Boise, ID (US); James M. Derderian, Boise, ID (US); Luke G. England, Portland, ME (US); Owen R. Fay, Meridian, ID (US)

Correspondence Address: PERKINS COIE LLP;PATENT-SEA, PO BOX 1247, SEATTLE, WA, 98111-1247, US

(73) Assignee: MICRON TECHNOLOGY, INC., Boise, ID (US)

(21) Appl. No.: 12/057,762

(22) Filed: Mar. 28, 2008

(51) Int. Cl. H01L 31/0203; H01L 23/552; H01L 21/304; H01L 31/18

(52) U.S. Cl. 257/432; 257/659; 438/462; 438/65; 257/E23.114; 257/E31.127; 257/E21.238

(57) ABSTRACT

A microelectronic device assembly with an integrated conductive shield is disclosed herein. The microelectronic device assembly includes a semiconductor substrate, an integrated circuit carried by the semiconductor substrate, a dielectric encapsulant encasing at least a portion of the semiconductor substrate. The microelectronic device assembly also includes a conductive shield in direct contact with at least a portion of the dielectric encapsulant and an interconnect extending through the semiconductor substrate and in direct contact with the conductive shield.

### TECHNICAL FIELD

The present disclosure is directed to conductive shield structures for suppressing electromagnetic interference (EMI) in microelectronic device assemblies and associated methods for making such structures.

### BACKGROUND

Semiconductor imagers typically include an array of photodiodes that can detect visible light with spatial resolution. However, EMI can impair the performance of imagers. For example, photodiodes typically cannot distinguish different types of radiation coming from different sources, and thus can generate dark current from background radiation even without being exposed to visible light. EMI can also introduce electrical noise that affects processing of electrical circuits associated with the imagers. In addition, EMI emitted from imagers and/or other components of a device (e.g., communication circuitry on a cellular phone) may interfere with one another to degrade device performance. Furthermore, increasing levels of component integration, radio frequency interference on a motherboard of a system, and FCC compliance may require imagers to be shielded from external electromagnetic emissions and/or may require shielding the imagers from emitting into an environment. As a result, EMI must be suppressed or eliminated for proper functioning of the device.

FIG. 1 illustrates an imager assembly 100 having an EMI suppressing structure in accordance with the prior art. As shown in FIG. 1, the imager assembly 100 includes an imager die 102, an objective lens 120 attached to a first surface 104a of the imager die 102, a plurality of solder balls 105 attached to a second surface 104b of the imager die 102, and an encapsulant 122 encapsulating the objective lens 120 and the imager die 102. The imager die 102 typically includes a sensor array 106 (e.g., a CMOS or CCD sensor array) at the first surface 104a and a plurality of vias 108 extending between the first and second surfaces 104a-b to electrically connect the sensor array 106 and/or other internal circuitry (not shown) of the imager die 102 to the solder balls 105. As shown in FIG. 1, the EMI suppressing structure 130 includes a metal housing that has a first opening 126a for receiving a portion of the objective lens 120 and a second opening 126b for receiving the encapsulated imager die 102 and the objective lens 120.

One drawback of the foregoing imager assembly 100 is that the EMI suppressing structure 130 is large and increases the footprint of the imager assembly 100. As shown in FIG. 1, the metal housing is larger than the imager die 102 to receive and enclose the encapsulated imager die 102. Such a large footprint, however, is undesirable because cell phones, cameras, and other portable devices are continually requiring smaller components. Accordingly, there is a need for an improved EMI suppressing structure that can reduce the footprint of the imager assembly.

### BRIEF DESCRIPTION OF THE DRAWINGS

FIG. 1 is a partially schematic cross-sectional view of an imager assembly with an EMI suppressing structure in accordance with the prior art.

FIG. 2 is a partially schematic cross-sectional view of a microelectronic device assembly having an integrated conductive shield in accordance with an embodiment of the disclosure.

FIGS. 3A-3I illustrate a process for forming the imager assembly shown in FIG. 2 in accordance with an embodiment of the disclosure.

FIG. 4 is a schematic diagram of a system that includes one or more microfeature dies in accordance with embodiments of the disclosure.

### DETAILED DESCRIPTION

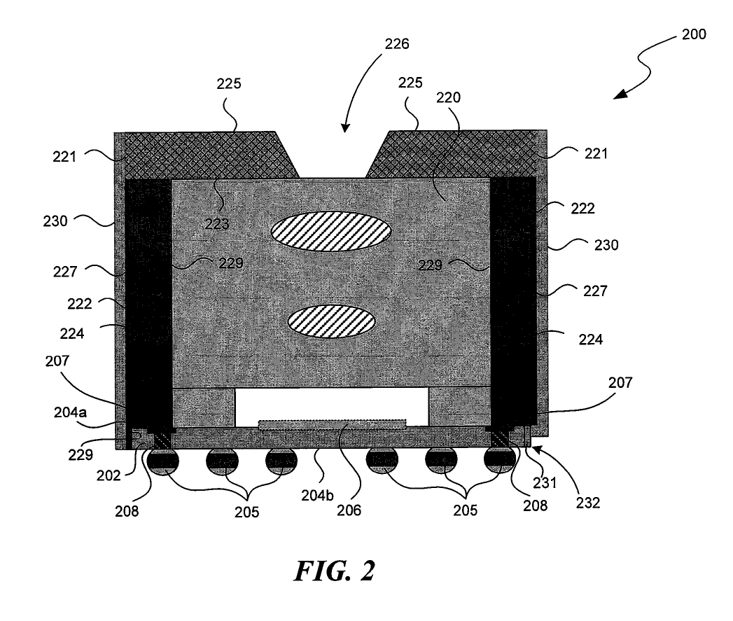

Specific details of several embodiments of the disclosure are described below with reference to microelectronic device assemblies having EMI suppressing structures and methods of manufacturing. Typical microelectronic device assemblies include microelectronic circuits or components, thin-film recording heads, data storage elements, microfluidic devices, and other products. Micromachines and micromechanical devices are included within this definition because they are manufactured using much of the same technology that is used in the fabrication of integrated circuits. Substrates can be semiconductor pieces (e.g., doped silicon wafers or gallium arsenide wafers), nonconductive pieces (e.g., various ceramic substrates), or conductive pieces. A person skilled in the relevant art will also understand that the disclosure may have additional embodiments, and that the disclosure may be practiced without several of the details of the embodiments described below with reference to FIGS. 2-4.

FIG. 2 is a partially schematic cross-sectional view of a microelectronic device assembly having an EMI suppressing structure in accordance with an embodiment of the disclosure. In the illustrated embodiment, the microelectronic device assembly is shown as an imager assembly 200. However, in other embodiments, the microelectronic device assembly can also include radio frequency transceivers and/or other suitable microelectronic devices.

As shown in FIG. 2, the imager assembly 200 can include an imager die 202, an objective lens 220 attached to a first surface 204a of the imager die 202, and a plurality of solder balls 205 attached to a second surface 204b of the imager die 202. The first and second surfaces 204a-b are generally opposite to one another. The objective lens 220 can be constructed from glass, polymers, a combination of glass and polymers, and/or other suitable transparent material. The objective lens 220 can be configured as a single layer or a multilayer structure. Optionally, in certain embodiments, the imager assembly 200 can also include a protective lens cover (not shown) proximate to the objective lens 220. The imager die 202 can include a sensor array 206 (e.g., a CMOS or a CCD sensor array) proximate to the first surface 204a, a plurality of bond sites 207, a plurality of vias 208 between the first and second surfaces 204a-b, and internal signal processing circuits (e.g., column/row-select circuits, analog signal processors, timing and control circuits, A/D converters, and digital signal processors). At least some of the bond sites 207 are in electrical communication with the sensor array 206 and/or the signal processing circuits, and the vias 208 electrically connect the bond sites 207 to the solder balls 205 for external access.

The imager assembly 200 can also include an encapsulant 222 and a hood 225. The encapsulant 222 at least partially encapsulates the imager die 202 and the objective lens 220. The hood 225 can be in direct contact with the top surface 223 of the objective lens 220, or the hood 225 can be attached to the top surface 223 with an adhesive layer (not shown). The hood 225 can also include an opening 226 for receiving a portion of the objective lens 220. The hood 225 can be constructed from a molded epoxy compound and/or other suitable polymeric material with sufficient strength for protecting and insulating the objective lens 220 and with sufficient opaqueness for blocking stray light from entering the objective lens 220. The hood 225 can also function as a carrier for the objective lens 220 during assembly. In one embodiment, the hood 225 can have the same composition as the encapsulant 222. In other embodiments, the hood 225 can have a different composition from the encapsulant 222.

The encapsulant 222 can include first encapsulant side surfaces 224 directly against corresponding side surfaces 229 of the objective lens 220 and second encapsulant side surfaces 227 opposite corresponding first encapsulant side surfaces 224. In the illustrated embodiment, the second encapsulant side surfaces 227 are generally aligned with corresponding tape side surfaces 221 and extend beyond an edge 229 of the imager die 202. In other embodiments, the second encapsulant side surfaces 227 can be offset from corresponding tape side surfaces 221. In further embodiments, the second encapsulant side surfaces 227 can be generally aligned with the edge 229 of the imager die 202 or extend inwardly from the edge 229.

The imager assembly 200 can further include an integrated conductive shield 230 for suppressing EMI. In the illustrated embodiment, the conductive shield 230 includes a layer of conductive material plated or otherwise adhered to the tape side surfaces 221 and the second encapsulant side surfaces 227. The conductive material can include copper, aluminum, nickel, gold, silver, platinum, and/or other suitable metal or metal alloys. The conductive material can also include carbon, doped polysilicon, and/or other conductive non-metallic material. In certain embodiments, the conductive shield 230 can include a layer of copper with a thickness of about 1 micrometer to about 10 micrometers. In other embodiments, the conductive shield 230 can include a layer of conductive material with other desired thicknesses. In further embodiments, the conductive shield 230 can be plated only onto the second encapsulant side surfaces 227 of the encapsulant 222, not onto the tape side surfaces 221. Even though the conductive shield 230 is shown to have a generally uniform thickness in FIG. 2, in certain embodiments, portions of the conductive shield 230 may have different thicknesses.

To electrically connect the conductive shield 230 to ground, the imager die 202 can include a shield interconnect 232 at the imager die 202. The shield interconnect 232 can be formed a notch 231 at a corner of the imager die 202 that extends from the first surface 204a to the second surface 204b. In certain embodiments, the notch 231 may be formed simultaneously with the vias 208 that connect the bond sites 207 to corresponding solder balls 205. In other embodiments, the notch 231 may be formed separately from forming the vias 208. The shield interconnect 232 can, for example, include a layer of copper, aluminum, and/or other conductive metal or metal alloy plated onto or into the notch 231. The imager die 202 can also include redistribution lines (not shown) at the second surface 204b for connecting the shield interconnect 232 to at least one of the solder balls 205. In other embodiments, the shield interconnect 232 can also include a slot, a channel, and/or other structures.

The shield interconnect 232 can be in electrical communication with the conductive shield 230. For example, in the illustrated embodiment, the conductive shield 230 extends toward the imager die 202 and is in direct physical contact with the shield interconnect 232 by covering a portion of the shield interconnect 232. In another embodiment, the conductive shield 230 can substantially completely cover the shield interconnect 232. In further embodiments, the conductive shield 230 can be spaced apart from the shield interconnect 232 and can be electrically coupled to the shield interconnect 232 by a trace, a wire, and/or other suitable electrical connector (not shown).

In operation, the conductive shield 230 can reduce or eliminate external electromagnetic, electrical, and/or magnetic interference to the imager die 202. For example, when the imager assembly 200 is exposed to an external EMI source (not shown), the external EMI source can induce charges in the conductive shield 230 which can be conducted to ground via the shield interconnect 232 and a corresponding solder ball 205. As a result, the conductive shield 230 can at least reduce dark current and/or other interference induced by the external EMI source.

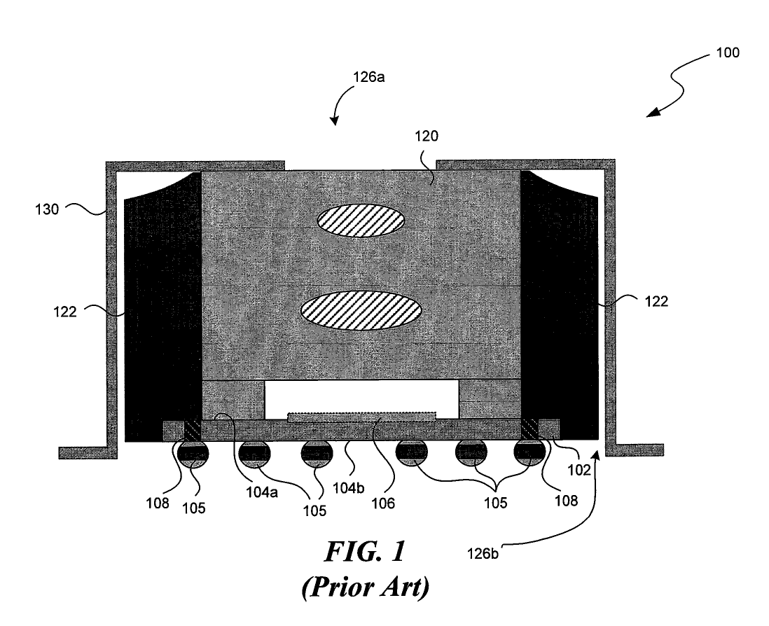

Several embodiments of the conductive shield 230 can have a smaller footprint than that of the prior art device shown in FIG. 1 because the conductive shield 230 is integrated into the imager assembly 200. As shown in FIG. 1, the conventional conductive shield 130 typically has a footprint larger than that of the imager die 102. As a result, the imager assembly 100 requires a large surface area when being mounted onto a substrate (e.g., a printed circuit board). In contrast, several embodiments of the conductive shield 230 shown in FIG. 2 can have a footprint that is proximately the same as or even smaller than the footprint of the imager die 202. As a result, the footprint of the imager assembly 200 can be reduced by as much as 25% compared to some conventional imager assemblies.

Even though the imager assembly 200 is described above as having one shield interconnect 232, in several embodiments, the imager assembly 200 can have more than one shield interconnect 232. For example, the imager assembly 200 can include two shield interconnects (not shown) located at opposite corners of the imager die 202. In other embodiments, the conductive shield 230 can also include a conductive layer (not shown) disposed on top of the hood 225. In further embodiments, the imager assembly 200 can also include lens covers and/or other suitable components in addition to the conductive shield 230 and shield interconnect 232.

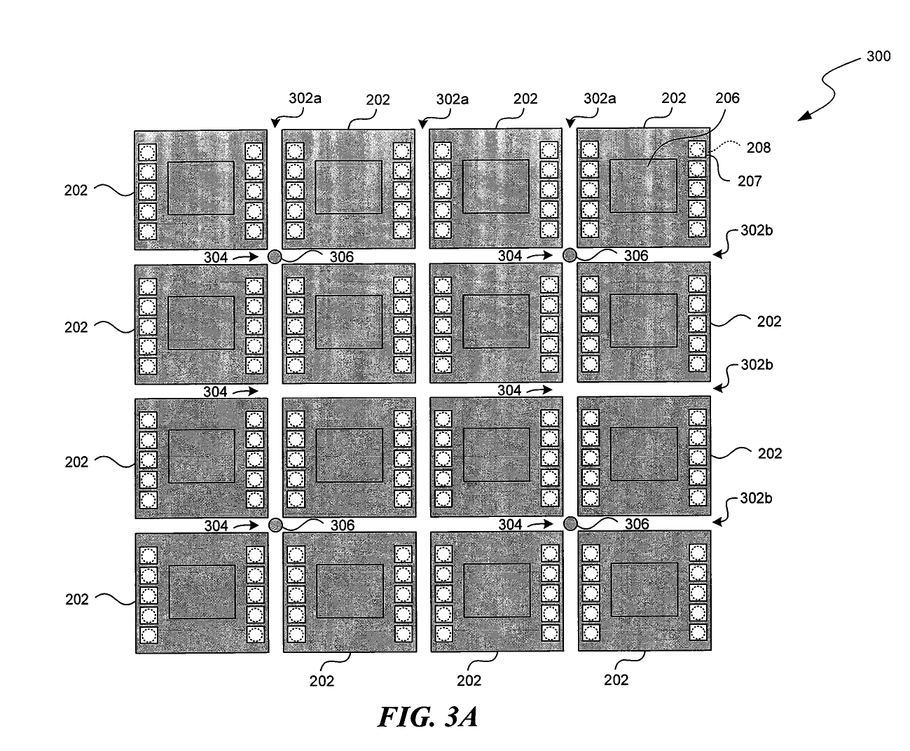

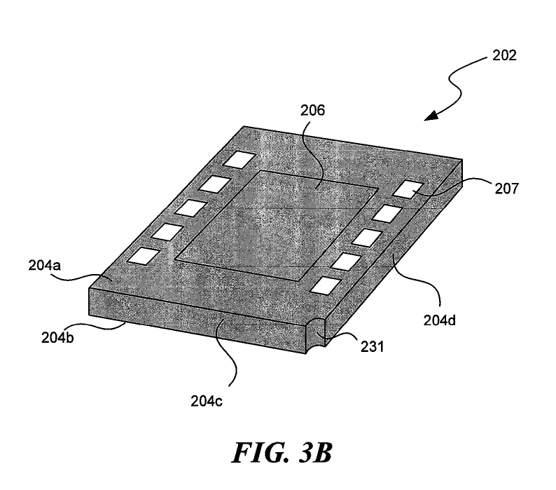

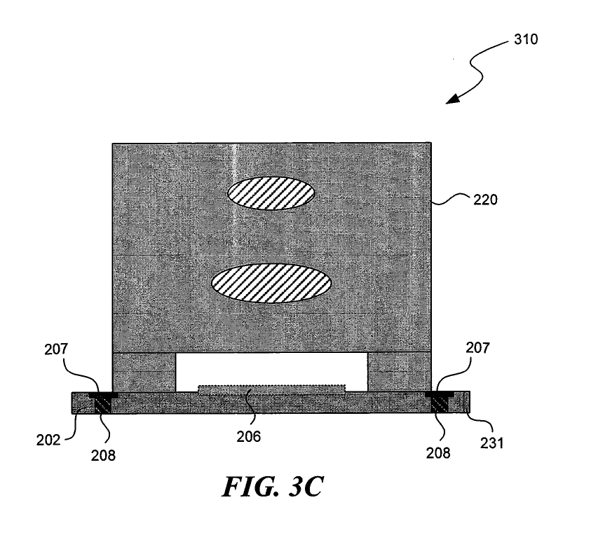

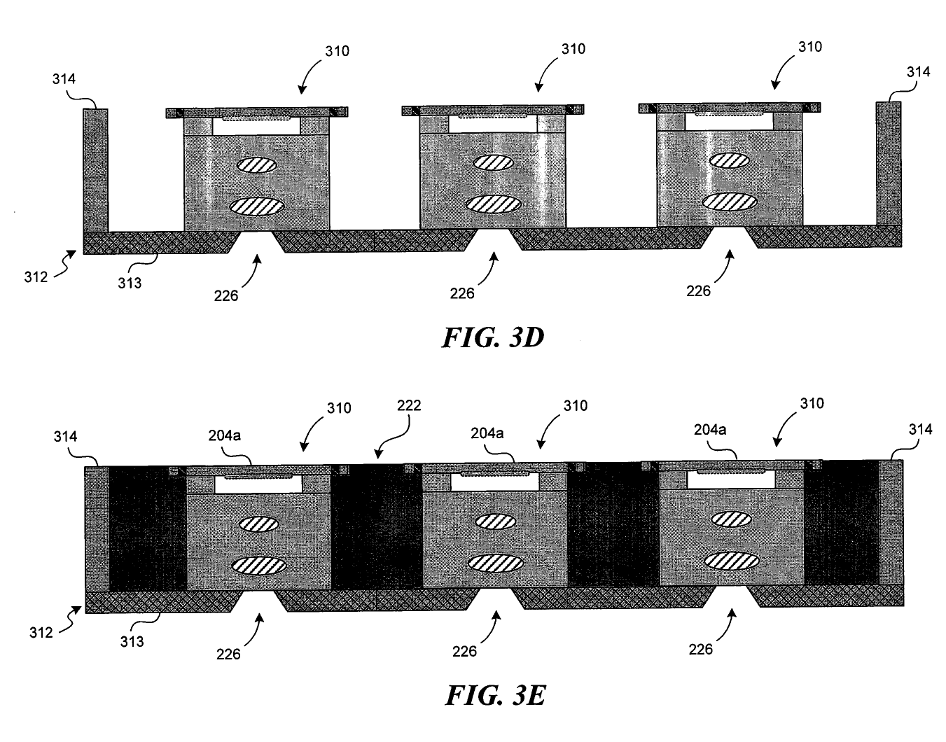

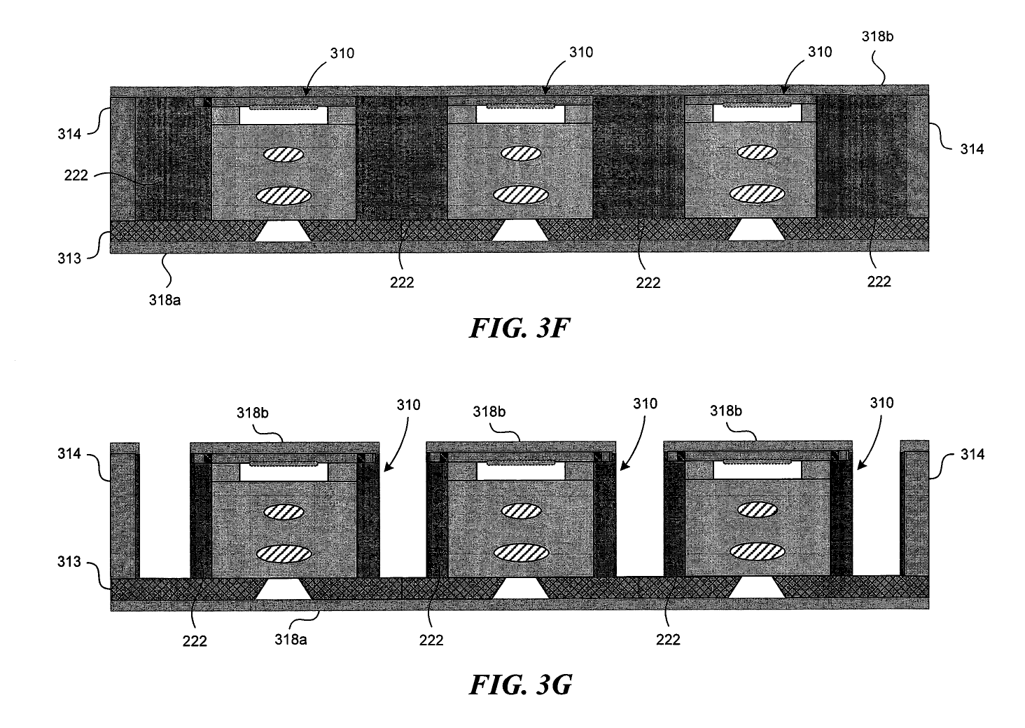

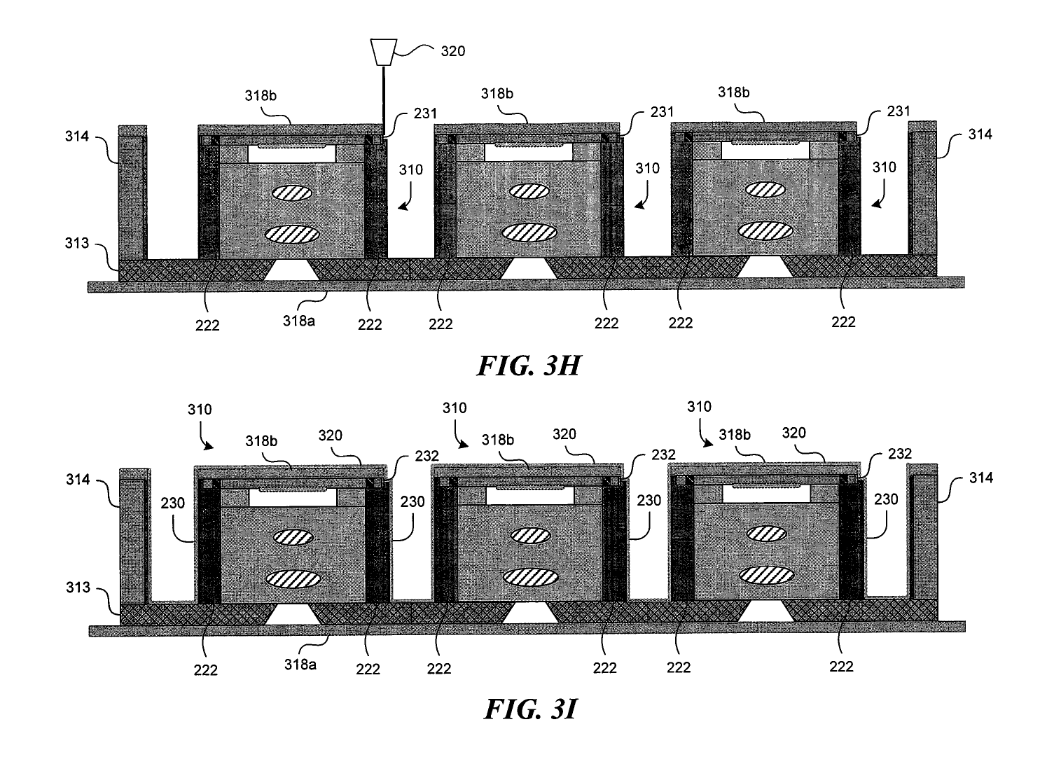

FIGS. 3A-3I illustrate stages of an embodiment of a process for forming the imager assembly 200 of FIG. 2. FIG. 3A illustrates an early stage of the process that includes forming a plurality of imager dies 202 in a workpiece 300. In the illustrated embodiment, sixteen imager dies 202 are shown; however, in other embodiments, any desired number of imager dies 202 can be formed in the workpiece 300. As described above with reference to FIG. 2, individual imager dies 202 can include a plurality of bond sites 207 and vias 208 (shown in phantom lines) proximate to the sensor array 206. Only one via 208 is marked for clarity.

As shown in FIG. 3A, the workpiece 300 includes first gaps 302a and second gaps 302b (typically referred to as “saw streets”) that separate each pair of adjacent imager dies 202 from one another. Individual first gaps 302a are transverse to the second gaps 302b such that the first and second gaps 302a-b form intersections 304. In the illustrated embodiment, the first gaps 302a have a first width and extend along a first direction, and the second gaps 302b have a second width generally equal to the first width and extend along a second direction generally normal to the first direction. In other embodiments, the first and second gaps 302a-b can have other relative dimensions and/or relative orientations.

After the imager dies 202 are formed, the process includes forming a plurality of vias 306 in the first and/or second gaps 302a-b. In the illustrated embodiment, the vias 306 have a generally cylindrical shape and are formed in selected intersections 304 such that each imager die 202 is proximate to only one of the vias 306. The vias 306 can have a diameter that is generally the same as or smaller than the first or second width. In other embodiments, the vias 306 can be formed in generally all the intersections 304, or at a suitable location along the first and/or second gaps 302a-b.

FIG. 3B illustrates a subsequent stage of the process, which includes singulating individual imager dies 202 along the first and second gaps 302a-b and at the intersections 304. In one embodiment, singulating individual imager dies 202 includes singulating along a center line of the first and/or second gaps 302a-b. In other embodiments, singulating individual imager dies 202 can include singulating along an off-centered line in the first or second gaps 302a-b.

As shown in FIG. 3B, after singulation, the imager die 202 has a generally rectangular cross section. The imager die 202 includes a first side 204c adjacent to a second side 204d. Both first and second sides 204c-d extend between the first and second surfaces 204a-b. The imager die 202 further includes a portion of the via 306 (FIG. 3A) forming the notch 231 between the first and second sides 204c-d. In the illustrated embodiment, the notch 231 has a generally curved surface between the first and second sides 204c-d. In other embodiments, the notch 231 can have a generally planar or other suitable surface.

FIGS. 3C-3I illustrate additional stages of the process, in which several details of the imager subassemblies 310 are not shown for clarity purposes. FIG. 3C illustrates another stage of the process in which an imager subassembly 310 is formed by attaching the objective lens 220 to the imager die 202, and FIG. 3D shows a subsequent stage in which a plurality of imager subassemblies 310 are placed onto a molding strip 312. The molding strip 312 includes a base 313 with openings 226 and dam portions 314 at least partially enclosing the base. As explained below, the base is cut at a later stage to form the hood 225 along the top surface of the objective lens 220 (FIG. 2).

FIG. 3E illustrates another stage of the process that includes dispensing the encapsulant 222 in liquid form into the molding strip 312 to fill voids between the dam portions 314 and the imager subassemblies 310. In the illustrated embodiment, the process also includes controlling an amount of the dispensed encapsulant such that the encapsulant 222 is generally aligned with the first surface 204a of individual imager dies 202. In other embodiments, the process also includes controlling an amount of the dispensed encapsulant such that the encapsulant 222 is offset from or otherwise not covering the first surface 204a. In further embodiments, the imager subassemblies 310 can also be encapsulated with the encapsulant 222 using transfer molding, injection molding, compression molding, and/or other suitable molding techniques.

FIG. 3F shows another stage of the process in which a first protection tape 318a is attached to the molding strip 312 and a second protection tape 318b is attached to the dam portions 314, the encapsulant 222, and the imager subassemblies 310. The protection tapes 318a-b can be UV release tapes and/or other suitable tape material.

FIG. 3G illustrates another stage of the process that includes partially singulating the encapsulated imager subassemblies 310. In the illustrated embodiment, partially singulating the encapsulated imager subassemblies 310 includes removing a portion of the encapsulant 222 between adjacent imager subassemblies 310 and between the dam portions 314 and corresponding imager subassemblies 310. The encapsulant 222 can be removed using laser ablation and/or other suitable techniques without damaging the molding strip 312. In other embodiments, the encapsulant 222 can be only partially removed. In further embodiments, at least a portion of the molding strip 312 can be removed.

FIG. 3H illustrates a subsequent stage of the process, which includes exposing the notches 231 by removing a portion of the second protection tape 318b and the encapsulant 222. In one embodiment, removing a portion of the second protection tape 318b includes using a laser to selectively ablate a portion of the second protection tape 318b and the encapsulant 222. In other embodiments, etching and/or other suitable techniques can also be used.

After the notches 231 are exposed, another stage of the process includes applying a layer of conductive material 320 onto the encapsulated imager subassemblies 310. As shown in FIG. 3I, a portion of the conductive material 320 is in the notches 231 to form the shield interconnects 232, and another portion of the conductive material 320 is deposited onto the encapsulant 222 to form the conductive shield 230. The layer of conductive material 320 can be applied by depositing copper, aluminum or another conductive material onto the imager subassemblies 310 using electroplating, sputtering, spraying, and/or other suitable deposition techniques. In the illustrated embodiment, the conductive material 320 is also deposited onto the second protection tape 318b. In other embodiments, an operator can select the second protection tape 318b to be resistant to the deposition process. As a result, a reduced amount or no conductive material is deposited onto the second protection tape 318b. In other embodiments, the conductive material 320 can be a pre-formed metal foil that is laminated to the imager subassemblies 310.

The process further includes completely singulating the imager subassemblies 310 by cutting through the conductive material 320 and the base 313, removing the first and second protection tapes 318a-b, and attaching the solder balls 205 (FIG. 2) to obtain the imager assembly 200 of FIG. 2. The remaining portions of the base 313 on the individual objective lenses of the imager subassemblies 310 define the hoods 225 (see FIG. 2). In one embodiment, removing the first and second protection tapes 318a-b can include applying UV radiation to activate the protection tapes and peeling them off from the imager assemblies 200. In other embodiments, removing the first and second protection tapes 318a-b can include laser ablation, etching, and/or other suitable techniques.

The process described above with reference to FIGS. 3A-3I can have additional and/or different process stages. For example, barrier layers can be deposited before depositing the layer of conductive material 320. Etch-stop or polish-stop layers can also be used when removing a portion of any deposited material.

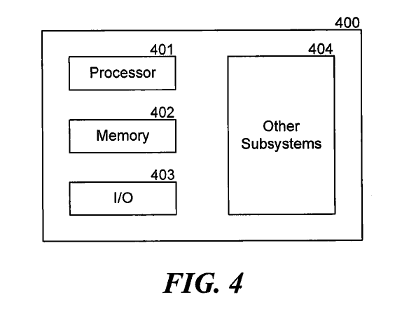

Individual imager assemblies 200 may be incorporated into any of myriad larger and/or more complex systems 400, a representative one of which is shown schematically in FIG. 4. The system 400 can include a processor 401, a memory 402, input/output devices 403, and/or other subsystems or components 404. Microfeature workpieces (e.g., in the form of microfeature dies and/or combinations of microfeature dies) may be included in any of the components shown in FIG. 4. The resulting system 400 can perform any of a wide variety of computing, processing, storage, sensor, and/or other functions. Accordingly, the representative system 400 can include, without limitation, computers and/or other data processors, for example, desktop computers, laptop computers, Internet appliances, and hand-held devices (e.g., palmtop computers, wearable computers, cellular or mobile phones, multiprocessor systems, processor-based or programmable consumer electronics, network computers, and mini computers). Another representative system 400 can include cameras, light sensors, servers and associated server subsystems, display devices, and/or memory devices. Components of the system 400 may be housed in a single unit or distributed over multiple, interconnected units, e.g., through a communications network. Components can accordingly include local and/or remote memory storage devices and any of a wide variety of computer-readable media, including magnetic or optically readable or removable computer disks.

From the foregoing, it will be appreciated that specific embodiments of the disclosure have been described herein for purposes of illustration, but that various modifications may be made without deviating from the disclosure. For example, many of the elements of one embodiment may be combined with other embodiments in addition to or in lieu of the elements of the other embodiments. Accordingly, the disclosure is not limited except as by the appended claims.

I claim:

1. A microelectronic device assembly, comprising:
a semiconductor substrate;
an integrated circuit carried by the semiconductor substrate;
a dielectric encapsulant encasing at least a portion of the semiconductor substrate;
a conductive shield in direct contact with at least a portion of the dielectric encapsulant; and
an interconnect extending through the semiconductor substrate and in direct contact with the conductive shield.

2. The microelectronic device assembly of claim 1 wherein the conductive shield is electrically grounded.

3. The microelectronic device assembly of claim 1 wherein the semiconductor substrate has a first surface, a second surface, and a generally rectangular cross section with a first side and a second side between the first and second surfaces, and wherein the interconnect includes a notch between the first side and the second side.

4. The microelectronic device assembly of claim 3 wherein the notch has a curved surface extending from the first side to the second side.

5. The microelectronic device assembly of claim 3 wherein the notch has a generally planar surface extending from the first side to the second side.

6. The microelectronic device assembly of claim 3 wherein the notch is coated with a layer of conductive material.

7. The microelectronic device assembly of claim 3 wherein the notch is coated with a layer of conductive material in direct physical contact with the conductive shield.

8. The microelectronic device assembly of claim 1 wherein the semiconductor substrate includes a plurality of solder balls at the second surface, and wherein the interconnect is electrically connected to at least one of the solder balls for external access.

9. An imager assembly, comprising:
an imager die having a first surface, a second surface opposite the first surface, a sensor array at the first surface, and a plurality of solder balls at the second surface;
an objective lens attached to the first surface of the imager die;
a dielectric encapsulant encapsulating at least a portion of the imager die and the objective lens;
a conductive shield in direct contact with at least a portion of the dielectric encapsulant; and
an interconnect extending from the first surface to the second surface of the imager die and electrically connecting the layer of conductive material to at least one of the solder balls at the second surface.

10. The imager assembly of claim 9 wherein the conductive shield includes a layer of conductive material selected from the group consisting of copper, aluminum, nickel, gold, silver, and platinum.

11. The imager assembly of claim 9 wherein the dielectric encapsulant includes a first side surface proximate to the objective lens and a second side surface opposite the first side surface, and wherein the conductive shield includes a layer of conductive material plated onto the second side surface of the dielectric encapsulant.

12. The imager assembly of claim 9, further comprising a hood in direct contact with the objective lens and a portion of the dielectric encapsulant.

13. The imager assembly of claim 12 wherein the conductive shield includes a layer of conductive material on at least a portion of the hood.

14. The imager assembly of claim 12 wherein the dielectric encapsulant includes a first side surface proximate to the objective lens and a second side surface opposite the first side surface, and wherein the hood includes a tape side surface generally aligned with the second side surface, and further wherein the conductive shield includes a layer of conductive material plated on at least a portion of the second side surface and the tape side surface.

15. The imager assembly of claim 14 wherein the hood further includes a top surface adjacent to the second side surface, and wherein the conductive shield includes a layer of conductive material coated on at least a portion of the top surface of the hood.

16. A process for forming a microelectronic device assembly, comprising:
forming a plurality of microelectronic devices in a semiconductor workpiece, adjacent microelectronic devices being separated from one another by a first gap extending in a first direction and by a second gap extending in a second direction transverse to the first direction, wherein the first and second gaps intersect each other at an intersection;
forming a via in the workpiece at the intersection; and
singulating individual microelectronic devices along the first and second gaps and at the intersection such that the via forms a notch at the corner of individual microelectronic devices.

17. The process of claim 16 wherein forming a plurality of microelectronic devices includes forming a plurality of microelectronic devices separated by a first gap having a first width and a second gap having a second width generally equal to the first width, and wherein forming a via includes forming a via that has a diameter generally equal to the first or second width.

18. The process of claim 16 wherein forming a plurality of microelectronic devices includes forming a plurality of microelectronic devices separated by a first gap and a second gap generally normal to the first gap.

19. The process of claim 16, further comprising forming a notch on individual microelectronic devices from a portion of the via.

20. The process of claim 19 wherein forming a notch includes forming a notch that includes a curved surface extending from a first side surface to a second side surface of individual microelectronic devices.

21. The process of claim 19 wherein forming a notch includes forming a notch that includes a planar surface extending from a first side surface to a second side surface of individual microelectronic devices.

22. A process for forming an imager assembly, comprising:
placing an imager subassembly on a molding strip, the imager subassembly having an objective lens proximate to the molding strip and an imager die attached to the objective lens, wherein the imager die has a notch extending from a first side to a second side of the imager die;
dispensing a dielectric encapsulant into the molding strip;
encapsulating the imager subassembly with the dispensed dielectric encapsulant;
exposing the notch on the imager die from the dielectric encapsulant; and
coating the dielectric encapsulant and the notch with a layer of conductive material.

23. The process of claim 22 wherein the imager die includes a sensor array at a first surface and a second surface opposite the first surface, and wherein exposing a notch on the imager die includes applying laser ablation to remove a portion of the dielectric encapsulant.

24. The process of claim 22 wherein coating the dielectric encapsulant and the notch includes electroplating, sputtering, and/or spraying the layer of conductive material onto the dielectric encapsulant and the notch.

25. The process of claim 22 wherein coating the dielectric encapsulant and the notch includes coating the dielectric encapsulant and the notch with a layer of copper, aluminum, or nickel with a thickness from about 1 micrometer to about 10 micrometers.
